(19) United States
(12) Patent Application Publication
(10) Pub. No.: US 2005/0174159 A1
(43) Pub. Date: Aug. 11, 2005

(54) Apparatus for voltage level shifting

(76) Inventors: Anton Rozen, Gedera (IL); Michael Priel, Herzliay (IL); Sergey Sofer, Rishori le-Zion (IL)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/055,751

(22) Filed: Feb. 10, 2005

(30) Foreign Application Priority Data
Feb. 11, 2004 (GB) 0402945.0

(51) Int. Cl. H03L 5/00

(52) U.S. Cl. 327/333

(57) ABSTRACT

An apparatus for voltage level shifting comprising a voltage shifter for converting a first input voltage to a second output voltage; a first semiconductor switch arrangement and a second semiconductor switch arrangement that are responsive to a control signal for switching the voltage shifter between a first operational state and a second operational state and thereby allow the voltage shifter to be placed in the first operational state when the first input voltage is within a first voltage region and to place the voltage shifter in the second operational state when the first input voltage is in a second voltage region.

The present invention relates to an apparatus for voltage level shifting.

With the ever increasing demand for electronic devices to be both mobile and multifunctional it has become increasingly important to improve battery life and reduce power consumption requirements for these devices.

One technique that has been developed to reduce power consumption in electronic circuits is power gating. Power gating allows different power supplies to be used to power different blocks within an integrated circuit IC, thereby allowing unused IC blocks to be switched off when not required and thus save power.

However, the use of separate power supplies can result in power supply voltage levels being different between different IC blocks, which can cause leakage currents to be generated when IC blocks having different power supply voltage levels are electrically coupled.

To minimise leakage currents caused by voltage level differences voltage level shifters can be used as an interface between different IC blocks, where a voltage level shifter ‘shifts’ an output voltage signal from one IC block to a voltage level that corresponds to the operating voltage of an electrically coupled IC block.

A further problem that can result from the use of separate power supplies (i.e. power gated IC blocks) can occur when an IC block is being powered on/powered off. During the IC block power on/power off process the output voltage signal will typically float and as such become unpredictable, which can cause leakage current to flow in IC blocks that are electrically coupled to the IC block that is performing the power on/power off process. This problem can, however, be solved by the insertion of a power gasket circuit that disables the output signal from the power gated block by presetting it to a stable voltage value.

Consequently, to minimise current leakage it is desirable to include a voltage level shifter and a power gasket within an interface between two power gated IC blocks.

One solution is to place the power gasket on the voltage level shifter output. However, while this will prevent an unknown voltage value being received by a power gated IC block during the power up/power down process the voltage level shifter will still receive an unknown voltage during this period, which can cause leakage current to occur in the voltage level shifter.

Another solution is to place the voltage level shifter on the power gasket output. However, in this configuration leakage current can occur in the power gasket if a voltage difference exists between the power gated IC block and the coupled power gasket.

It is desirable to improve this situation.

In accordance with a first aspect of the present invention there is provided an apparatus for voltage level shifting according to claim 1.

An embodiment of the invention will now be described, by way of example, with reference to the drawings, of which:

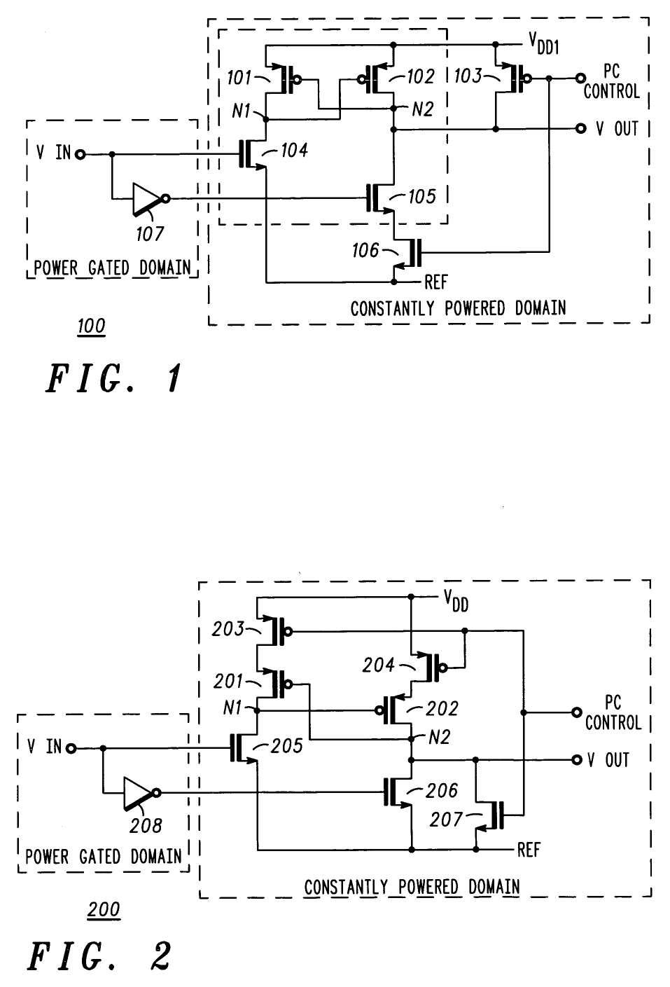

FIG. 1 illustrates an apparatus for voltage level shifting according to a first embodiment of the present invention;

FIG. 2 illustrates an apparatus for voltage level shifting according to a second embodiment of the present invention.

FIG. 1 shows a voltage level shifter according to a first embodiment having a first PMOS field effect transistor FET 101, a second PMOS FET 102, a third PMOS FET 103, a first NMOS FET 104, a second NMOS FET 105, a third NMOS FET 106 and an inverter 107.

The first PMOS FET 101 has a current path that is formed between a first power supply voltage VDD1, which corresponds to the power supply voltage of a constantly power gated IC block to which a voltage signal is to be input, and a first node N1. The second PMOS FET 102 has a current path that is formed between the first power supply voltage VDD1 and a second node N2, where the second node N2 is coupled to the output V_out of the voltage level shifter. Gate electrodes of the first PMOS FET 101 and the second PMOS FET 102 are cross-coupled to the second node N2 and first node N1 respectively.

The first NMOS FET 104, which serves as an input transistor, has a current path formed between the first node N1 and a reference voltage Ref (for example ground). The gate electrode of the first NMOS FET 104 is coupled to the input V_in of the voltage level shifter.

The second NMOS FET 105, which also serves as an input transistor, has a current path formed between the second node N2, and the third NMOS FET 106. The gate electrode of the second NMOS FET 105 is coupled to the output of the inverter 107.

The third NMOS FET 106, which is coupled between the second NMOS FET 105 and the reference voltage Ref, has its gate electrode coupled to a control input PG_control.

The third PMOS FET 103 has a current path that is formed between the first power supply voltage VDD and the second node N2. The gate electrode of the third PMOS FET 103 is coupled to the control input PG_control.

The inverter 107, which operates in the power supply domain of the power gated IC block from which a voltage signal is being received, has its input coupled to the voltage level shifter input V_in and, as stated above, the output of the inverter 107 is coupled to the gate of the second NMOS FET 105.

The third PMOS FET 103 acts as a first semiconductor switch arrangement and the third NMOS FET 106 acts as a second semiconductor switch arrangement, however, as illustrated in the second embodiment described below different semiconductor switch configurations can be used to form the semiconductor arrangements. As described below, the first semiconductor switch arrangement is used to ensure a stable voltage value is output from the voltage level shifter 100 when the power gated IC block is being powered on/powered off. While the first semiconductor switch arrangement and second semiconductor switch arrangement are used to allow the voltage level shifter 100 to perform voltage level shifting when the power gated IC block is not being powered on/powered off.

The operation of the voltage level shifter 100 will now be described.

During normal operation of the voltage level shifter 100, when power gasket capability is not required (i.e. during operation of the voltage level shifter 100 when the connected power gated IC block is not being powered on/powered off), the control input signal PF_control is set high, causing the third NMOS FET 106, which acts as a semiconductor switch, to switch on and the third PMOS FET 103, which also acts as a semiconductor switch, to switch off.

If, in this operational state (i.e. the third NMOS FET 106 is switched on and the third PMOS FET 103 is switched off), the voltage level shifter input V_in is set high the first NMOS FET 104 is caused to switch on, and the second NMOS FET 105, which is coupled to the input V_in via the inverter 107, is switched off. Typically, the voltage level shifter input V_in is considered as being high if the input voltage is in a predetermined voltage region, for example if the voltage input range is between 0 to 1 an input voltage of 0.5 to 1.0 might be regarded as high and an input voltage of 0 to 0.5 might be regarded as low.

The effect of the first NMOS FET 104 being switched on is to lower the voltage level at the first node N1 thereby pulling down the gate of the second PMOS FET 102, which causes the second PMOS FET 102 to switch on. This correspondingly causes the voltage at the second node N2 to increase which causes the first PMOS FET 101 to switch off. Correspondingly, the voltage level shifter voltage output V_out is set to substantially the same value as the first power supply voltage VDD.

If the voltage level shifter input V_in is set low the first NMOS FET 104 is caused to switch off and the second NMOS FET 105, which is coupled to the input V_in via the inverter 107, is switched on.

The effect of the second NMOS FET 105 being switched on is to lower the voltage level at the second node N2 thereby pulling down the gate of the first PMOS FET 101, which causes the first PMOS FET 101 to switch on. This correspondingly causes the voltage at the first node N1 to increase causing the second PMOS FET 102 to switch off. Correspondingly, the voltage level shifter output is set to a low voltage substantially the same as the reference voltage, for example less than a couple of mV.

When the voltage level shifter 100 is required to implement power gasket capability (for example, during the power on/power off process of a coupled IC block or constant power off state) the control input signal PG_control is set low, which causes the third NMOS 106 to switch off and the third PMOS FET 103 to switch on. When the voltage level shifter 100 is in this operational state the switching on of the third PMOS FET 103 causes the voltage level shifter voltage output V_out to be set to substantially the same value as the first power supply voltage VDD, independent of the voltage level shifter input signal V_in, further when the third PMOS 103 is switched on this causes the first PMOS 101 to be switched off. Accordingly, the states of the first NMOS FET 104, and the second NMOS FET 105 are not relevant.

FIG. 2 shows a voltage level shifter 200 according to a second embodiment having a first PMOS FET 201, a second PMOS FET 202, a third PMOS FET 203, a fourth PMOS FET 204, a first NMOS FET 205, a second NMOS FET 206, a third NMOS FET 207 and an inverter 208.

A first current path is formed between a first power supply voltage VDD, which corresponds to the power supply voltage of a constantly powered IC block to which a voltage signal is to be input, the third PMOS FET 203, the first PMOS FET 201, the first NMOS FET 205 and a reference voltage Ref (for example ground).

A first node N1 is formed between the first PMOS FET 201 and the first NMOS FET 205.

A second current path is formed between the first power supply voltage VDD the fourth PMOS FET 204, the second PMOS FET 202, the second NMOS FET 206 and the reference voltage Ref.

A second node N2 is formed between the second PMOS FET 202 and the second NMOS FET 206.

The third NMOS FET 207 has a current path that is formed between the reference voltage Ref and the second node N2.

The gate electrodes of the first PMOS FET 201 and the second PMOS FET 202 are cross-coupled to the second node N2 and the first node N1 respectively.

The gate electrode of the first NMOS FET 205, which serves as an input transistor, is coupled to the input of the voltage level shifter V_in.

The gate electrode of the second NMOS FET 206, which also serves as an input transistor, is coupled to the output of the inverter 208.

The gate electrodes of the third NMOS FET 207, the third PMOS FET 203 and the fourth PMOS FET 204 are coupled to a control input PG_control.

The inverter 208, which operates in the power supply domain of the power gated IC block from which a voltage signal is being received, has its input coupled to the voltage level shifter input V_in and, as stated above, the output of the inverter 208 is coupled to the gate of the second NMOS FET 206. The third NMOS FET 207 acts as a first semiconductor switch arrangement and the third PMOS FET 203 and the fourth PMOS FET 204 acts as a second semiconductor switch arrangement. As described below, the first semiconductor switch arrangement is used to ensure a stable voltage value is output from the voltage level shifter 200 when the power gated IC block is being powered on/powered off. While the first semiconductor switch arrangement and second semiconductor switch arrangement are used to allow the voltage level shifter 200 to perform voltage level shifting when the power gated IC block is not being powered on/powered off.

The operation of the voltage level shifter 200 will now be described.

During normal operation of the voltage level shifter 200, when power gasket capability is not required (i.e. during operation of the voltage level shifter 200 when the connected power gated IC block is not being powered on/powered off), the control input signal PG_control is set low, which causes the third NMOS FET 207, which acts as a semiconductor switch, to switch off and the third PMOS FET 203 and fourth PMOS FET 204, which also act as semiconductor switches, to switch on.

If, in this operational state (i.e. the third NMOS FET 207 is switched off and the third PMOS FET 203 and fourth PMOS FET 204 are switched on), the voltage level shifter input V_in is set high the first NMOS FET 205 is caused to switch on, and the second NMOS FET 206, which is coupled to the input via the inverter 208, is switched off.

The effect of the first NMOS FET 205 being switched on is to lower the voltage level at the first node N1 thereby pulling down the gate of the second PMOS FET 202, which causes the second PMOS FET 202 to switch on. This correspondingly causes the voltage at the second node N2 to increase which causes the first PMOS FET 201 to switch off. Correspondingly, the voltage level shifter voltage output V_out is set to substantially the same value as the first power supply voltage VDD.

If the voltage level shifter input V_in is set low the first NMOS FET 205 is caused to switch off and the second NMOS FET 206, which is coupled to the input via the inverter 208, is switched on.

The effect of the second NMOS FET 206 being switched on is to lower the voltage level at the second node N2 thereby pulling down the gate of the first PMOS FET 201, which causes the first PMOS FET 201 to switch on. This correspondingly causes the voltage at the first node N1 to increase which causes the second PMOS FET 202 to switch off. Correspondingly, the voltage level shifter output V_out is set to a low voltage substantially the same as the reference voltage Ref for example less than a couple of mV.

When the voltage level shifter 200 is required to implement power gasket capability (for example, during the power on/power off process of a coupled IC block or constant power off state) the control input signal PG_control is set high, which causes the third NMOS FET 207 to switch on and the third PMOS FET 203 and fourth PMOS FET 204 to switch off. When the voltage level shifter 200 is in this operational state the switching on of the third NMOS FET 207 causes the voltage level shifter voltage output V_out to be set to substantially the same value as the reference voltage Ref, independent of the voltage level shifter input signal. Accordingly, the states of the first NMOS FET 205, the second NMOS FET 206, the first PMOS FET 201 and the second PMOS FET 202 are not relevant.

1. An apparatus for voltage level shifting comprising a voltage shifter for converting a first input voltage to a second output voltage; a first semiconductor switch arrangement and a second semiconductor switch arrangement that are responsive to a control signal for switching the voltage shifter between a first operational state and a second operational state and thereby allow the voltage shifter to be placed in the first operational state when the first input voltage is within a first voltage region and to place the voltage shifter in the second operational state when the first input voltage is in a second voltage region.

2. An apparatus according to claim 1, wherein the voltage shifter comprises a differential amplifier.

3. An apparatus according to claim 1 wherein the first semiconductor switch arrangement comprises a PMOS FET.

4. An apparatus according to claim 1, wherein the second semiconductor switch arrangement comprises an NMOS FET.

5. An apparatus according to claim 1, wherein the first semiconductor switch is arranged to set the second output voltage to a predetermined voltage in response to the control signal being applied to the first semiconductor switch.

6. An apparatus for voltage level shifting comprising a voltage shifter for converting a first input voltage to a second output voltage; and a first semiconductor switch arranged to set the second output voltage to a predetermined voltage in response to a control signal being applied to the first semiconductor switch.
